(19) United States
(12) Patent Application Publication
(10) Pub. No.: US 2006/0219325 A1
(43) Pub. Date: Oct. 5, 2006

(54) Method for producing alpha-alumina layer-formed member and surface treatment

(75) Inventor: Toshimitsu Kohara, Takasago-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Kobe Seiko Sho (Kobe Steel, Ltd.), Kobe-shi (JP)

(21) Appl. No.: 11/350,007

(22) Filed: Feb. 9, 2006

(30) Foreign Application Priority Data
Mar. 31, 2005 (JP) 2005-102445

(51) Int. Cl. C23C 14/48

(52) U.S. Cl. 148/239

(57) ABSTRACT

The present invention provides a method for producing an α-alumina-formed member, comprising (1) a process for forming an alumina layer of α-type crystal structure on at least a partial surface of a base material; and (2) a process for performing an ion bombardment treatment to the surface of the resulting alumina layer. With an α-alumina film formed thereon according to this method, the tool life can be extended in case of a tool, and the frictional resistance can be reduced in case of a sliding member, a metal mold and the like.

### BACKGROUND OF THE INVENTION

1. Field of the Invention

The present invention relates to a cutting tool such as a tip, a drill or an end mill, a sliding member (automotive sliding member, etc.) and a metal mold, particularly, to a method for producing a member with α-alumina layer formed on a surface thereof, and a surface treatment method therefor.

A member such as the cutting tool, the sliding member or the metal mold generally comprises a hard film of titanium nitride, titanium aluminum nitride or the like formed on a surface of a base material of high-speed steel, cemented carbide or the like, since excellent wear resistance and sliding characteristic are demanded therefor. To enhance heat resistance of the member further, an aluminum oxide having a corundum structure (also referred to as hexagonal alumina or α-alumina) is often formed on the hard film. The hard film and the aluminum oxide are generally formed by use of a method such as chemical vapor deposition method (hereinafter also referred to as CVD method) or physical vapor deposition method (hereinafter referred often to as PVD method). Particularly, the PVD method is suitably adapted since it is superior to the CVD method in terms that an α-alumina layer can be formed at a relatively low temperature, and thermal deformation of the base material can be prevented (refer to Japanese Patent Laid-Open No. 2002-53946 and European Patent No. 1553210A1).

It is disclosed in Japanese Patent Laid-Open No. 2002-53946 to form an oxide film of corundum structure having a lattice parameter of 4.779 Å or more and 5.000 Å or less and a film thickness of 0.005 μm or more as an under layer and form an α-alumina film on this under layer by use of the PVD method. Further, a method for forming α-alumina on a TiAlN film excellent in heat resistance and wear resistance, which has recently been used for a hard film for tool, by use of the PVD method is disclosed in European Patent No. 1553210A1. In this document, the α-alumina is also formed after oxidizing the surface of the TiAlN hard film.

However, even in a cutting tool with the thus-formed α-alumina film, the tool life was often shortened by its use in a severe condition or for machining of a highly viscous work material. Further, the formation of the α-alumina layer on a surface of a sliding member or metal mold also sometimes caused an increase in frictional resistance on a contact surface, which could adversely affect the performance of the sliding member or metal mold.

On the other hand, techniques for smoothing an α-alumina layer surface in order to minimize the frictional resistance of the α-alumina layer surface is disclosed in U.S. Pat. Nos. 5,766,782 and 5,487,625. In the techniques disclosed in these documents, the surface is smoothed by a wet spray treatment using A₂O₃powder. However, since the smoothing by such a method requires much time and labor, a method for further efficiently smoothing the α-alumina layer surface has been demanded.

### SUMMARY OF THE INVENTION

From the viewpoint of such circumstances, the present invention has an object to provide a technique capable of extending the tool life in a tool and reducing the frictional resistance in a sliding member, a metal mold and the like even in case where an α-alumina layer is formed on such a member, and efficiently realize this technique.

A method for producing an α-alumina layer-formed member according to the present invention in which the above problems could be solved comprises:

(1) a process for forming an alumina layer of α-type crystal structure on at least a partial surface of a base material; and

(2) a process for performing ion bombardment treatment to the surface of the resulting alumina layer. According to the present invention, the tool life can be extended, and the frictional resistance in the sliding member, metal mold or the like can be reduced.

The ion bombardment treatment is preferably performed by use of a rare gas ion or a metal ion in plasma.

Further, the alumina layer is preferably formed by means of physical vapor deposition. At that time, the above processes (1) and (2) are preferably performed within the same apparatus.

A process for preliminarily forming a hard film as an under layer of the alumina layer of α-type crystal structure to be formed in the process (1) is preferably added as a pre-process of the process (1). At that time, the hard film is preferably TiAlN.

The “alumina of α-type crystal structure” (also referred to as “α-alumina” in the specification) means an alumina mainly composed of α-crystal structure (hexagonal structure), and the α-type crystal structure in the alumina layer is 70% or more, preferably 90% or more, and further preferably 100%, since excellent heat resistance can be exhibited.

According to the method for forming an α-alumina layer-formed member of the present invention, the smoothness of the α-alumina layer surface can be efficiently enhanced in order to extend the tool life. In case of the sliding member, the metal mold and the like, the frictional resistance can be reduced.

### BEST MODE FOR CARRYING OUT THE INVENTION

In order to solve the above-mentioned problems, the present inventors pursued studies and evaluated the surface property and the machinability for alumina films formed in several conditions. As a result, it could be confirmed that even an α-alumina film excellent in heat resistance or oxidation resistance causes deterioration of the machinability by adhesion of work material or the like in a certain machining condition, the machinability can be improved by smoothing the alumina film surface, and the alumina film surface can be efficiently smoothed by the ion bombardment treatment, and the present invention was attained.

In more detail, the α-alumina film has the characteristic that grains are largely grown in a columnar shape from the vicinity of a base material or an under layer to an alumina surface layer in its deposition process, and a number of elevated mountain-shaped irregularities are formed on the film surface to increase the surface roughness. Electron microscopic images of α-alumina film formed on a TiAlN film are shown in FIGS. 1 and 2. FIG. 1 is a TEM (transmission electron microscopic) image of a section thereof, and FIG. 2 is a SEM (scanning electron microscopic) image of a surface thereof In case of an alumina film of α-type crystal structure, as is apparent from the TEM image of FIG. 1, grains are largely grown in a columnar shape from the vicinity of the bed (a base material or a film formed on the base material: TiAlN film in the example of this drawing) to the alumina surface layer in its deposition process, with a grain size of several hundreds nm to several μm near the film surface layer. Therefore, as shown in FIG. 2, a number of elevated mountain-shaped irregularities are observed on the film surface. The surface roughness of the α-alumina film tended to increase (rough), while the grains of alumina of amorphous structure or γ-crystal structure are small. Further, compared with a TiN film or TiAlN film which is frequently used as a heat resisting and wear resisting film similarly to the α-alumina film, the surface roughness of the α-alumina film also tended to increase (rough). This high surface roughness was apt to cause the adhesion of work material to tool in the cutting tool with the α-alumina film formed thereon, resulting in shortening of the tool life, and the increase in friction resistance in the sliding member or metal mold with the α-alumina film formed thereon.

In the present invention, therefore, the surface of the α-alumina film (alumina layer of α-type crystal structure) was subjected to the ion-bombardment treatment. According to this, projections (sharply protruding parts of α-grains) on the α-alumina film surface are scraped by collision of ion, and the surface can be efficiently smoothed. FIG. 3 is a SEM image of an α-alumina film after subjected to the ion bombardment treatment. As shown in FIG. 3, the sharply-pointed parts of large grains of α-alumina are rounded, and the shape of the grains is also broken and flattened. By smoothing the surface in this way, in case of a tool, the adhesion of work material to tool can be prevented so as to improve the tool life. Further, reduction in working accuracy, limitation of machinable work material and the like, which are resulted from the adhesion, can be also overcome. The frictional resistance can be reduced in case of the sliding member or metal mold.

The gas ion for the ion bombardment treatment can be obtained by generating gas plasma, for example, by performing a discharge in a vacuum chamber to which gas is introduced (A. thermionic emission from a filament by heating a thermion emitting filament by carrying current and further applying a voltage between the filament and the chamber; B. glow discharge or arc discharge by applying a voltage between electrodes; or the like).

As the gas, rare gases (e.g., He, Ne, Ar, Kr, Xe, etc.) are recommended. The rare gases are excellent in the point that there is no possibility of corroding the base material, the film, the apparatus and the like, or reacting with the base material to form new compounds. A preferable rare gas is Ar. Ar is inexpensive and enables an efficient ion bombardment treatment. The metal ion can be generated from its electrode (metal), for example, at the time of the arc discharge or glow discharge in vacuum or in a gas atmosphere. As the metal of the metal ion, Ti, Al and the like can be used. Otherwise, a metal (Ti, Al, etc.) for forming the hard film described later, which is used as the under layer of α-alumina, can be used as the electrode in order to generate the metal ion from the electrode.

The ion generating condition (method) is not limited to the above-mentioned method as far as the ion sufficient to scrape the α-alumina layer can be obtained, and can be properly set according to the gas pressure in the chamber or the collision condition of the ion with the base material. A specific example is as follows. Namely, when a rare gas ion, for example, Ar ion is generated by use of thermionic emission, it is recommended to set the current to be carried between the thermion emitting filament and the chamber to 1 A or more, preferably to 5 A or more, and further preferably to 7 A or more. The rare gas plasma can be generated in a higher density as the current is larger. However, an excessively large current leads to an excessively increased plasma density, which tends to cause arcing on the base material and facilitate local etching of protruding parts of the base material. Therefore, the cutting edge is more easily rounded in the tool field. Further, the base material temperature is apt to increase, facilitating the thermal deformation of the base material. It is recommended thus to set the current to 50 A or lower, preferably to 30 A or lower, and further preferably to 20 A or lower. At that time, it is recommended to set the pressure of the rare gas to about 10 Pa or less, preferably to about 7 Pa or less, and further preferably to about 5 Pa or less. However, if the quantity of the rare gas to be introduced to the chamber is reduced to excessively reduce its pressure, the plasma becomes difficult to generate (or an increase in the current quantity to be carried to the filament is needed since it is difficult to obtain high-density plasma), resulting in an increased cost. Therefore, it is recommended to set the pressure of the rare gas to be introduced to the chamber to 0.1 Pa or more, preferably to 0.5 Pa or more, and further preferably to 1 Pa or more. When a metal ion is generated, the arc discharge is performed, for example, between an arc discharge cathode mounted with a metal target and the chamber in vacuum or in a gas atmosphere, whereby the ion of the metal used for the target can be obtained. If the arc discharge current is too small, it is difficult to continue a stable discharge, and if the current is excessively large, the heat load to the cathode or target is excessively increased to cause breakage of the apparatus. Therefore, the arc discharge current is preferably set to about 50-200 A.

It is preferred to efficiently collide the generated ion to the α-alumina layer (base material). The ion can be efficiently pulled into the base material (α-alumina film surface), for example, by applying a bias voltage (negative bias voltage, pulse bias voltage with reversed polarities, or the like), and a bombardment effect can be improved.

The bias voltage is desirably set to a negative value, for example, 100V or more, preferably to 200V or more, and further preferably to 250V or more in terms of the absolute value. The larger the bias voltage is, the more the bombardment effect can be improved. However, if the bias voltage is excessively high, an excessively increased energy of the ion entering the base material (α-alumina layer surface) easily causes the arcing or local etching as described above, which may then cause troubles such as rounding of the tool cutting edge or an excessively increased base material temperature. Accordingly, it is recommended to set the bias voltage preferably to a negative value, for example, to 1000V or less, preferably to 700V or less, and further preferably to 500V or less in terms of the absolute value.

When a pulse bias voltage is applied to the base material, the frequency is set, for example, to 10 kHz or more, preferably to 15 kHz or more, and further preferably to 20 kHz or more. An excessively low frequency tends to cause the arcing. The upper limit of the frequency is not particularly limited. However, since the power supply cost is generally increased as the frequency is increased, the frequency is set to about 500 kHz or less (e.g., about 300 kHz or less).

The duration of the ion bombardment treatment can be properly set according to the above-mentioned conditions (the gas pressure in the chamber, the ion generation condition, the ion collision condition and the like). It is frequently set to 5 minutes or more and 1 hr or less.

The member to be subjected to the ion bombardment treatment can include an α-alumina layer formed on at least a partial surface of a base material, and a known method such as physical vapor deposition method (PVD method) or chemical vapor deposition method (CVD method) can be applied to the formation thereof. Particularly, the thermal deformation of the base material can be easily prevented by using the PVD method (particularly, reactive sputtering, for example, reactive sputtering using a magnetron sputtering cathode such as an unbalanced magnetron (UBM) sputtering cathode). According to the PVD method, the formation of α-alumina layer and the ion bombardment treatment can be performed in the same apparatus, and the production process of the α-alumina layer-formed member can be simplified. Namely, the apparatus used in the ion bombardment treatment has a specification relatively similar to that of the apparatus used in the PVD method. Therefore, when the formation of α-alumina layer is performed by the PVD method, the ion bombardment treatment can be performed in the same apparatus for the formation of α-alumina layer without needing a large change in the specification.

The alumina layer may be formed directly on the base material, but is desirably laminated on another layer (an under layer: particularly, a hard film) formed on the base material. If the hard film is formed between the α-alumina layer and the base material, the wear resistance of the resulting α-alumina-formed member can be improved.

Examples of the hard film include a compound layer composed of one or more elements selected from elements of the groups IVa, Va, and VIa, Al, Si, Fe, Cu, Y and the like and one or more elements selected from C, N, B, O and the like, and a laminate thereof. Preferred examples of the compound layer include a Cr-based hard film (CrN, etc.), a Ti-based hard film (TiN, TiCN, TiAlN, TiSiN, etc.) and a TiCr-based hard film (TiAlCrN, etc.). Among them, the Ti-based hard film, particularly, TiAlN is preferred. The hard film can be formed by applying a known method such as the PVD method or CVD method. The PVD method (particularly, reactive sputtering, arc ion plating, etc.) is preferably used for the formation from points such that the thermal deformation of the base material can be easily prevented, and the same apparatus can be used.

The base material can be properly selected according to the use of the resulting α-alumina layer-formed member. Specifically, cemented carbide, cermet, high-speed tool steel and the like can be suitably adapted in case of obtaining a cutting tool.

The base material surface and the under layer surface can be subjected to a chemical treatment (e.g., oxidation treatment, nitriding treatment, or carburization treatment) prior to the lamination onto the α-alumina layer to form a reactive layer. Further, a roughness changing treatment (a smoothing treatment such as polishing, or a surface roughing treatment such as flawing or ion bombardment) may be performed simultaneously with or separately from the chemical treatment. These chemical treatment and roughness changing treatment may not be performed.

A layer composed of a material having the same crystal structure as α-alumina is preferably formed on the surface subjected to lamination of the α-alumina layer (precisely, between the α-alumina layer and the base material surface or between the α-alumina layer and the under layer surface in case of forming the under layer) prior to the lamination to the α-alumina layer. According to this, the adhesion of the surface subjected to lamination (the base material, the under layer, etc.) with the α-alumina layer can be enhanced. In addition to αAl₂O₃, oxides such as αCr₂O₃ and αFe₂O₃ are preferred since they have the same corundum structure as αAl₂O₃. These αCr₂O₃ and αAl₂O₃ can be formed, for example, on a surface of CrN or TiAlN by oxidizing the surface.

In the present invention, another film (e.g., the above-mentioned hard film) may be laminated further as an upper layer of the α-alumina film. Since the surface of the α-alumina layer is smoothed in the present invention, the surface of the hard film, even if laminated on the α-alumina layer, can be smoothed, and the effect of the present invention can be kept.

In the present invention, the α-alumina layer, the upper layer and the under layer are not necessarily formed over the whole surface of the base material, but formed at least in a part needing the enhancement of wear resistance or the reduction of frictional resistance. The thickness of the α-alumina layer, the upper layer and the under layer can be properly selected according to the use of the α-alumina-formed member. Particularly, if the thickness of the α-alumina layer is excessively small, a sufficient effect may not be obtained, and it is thus recommended to set the thickness to 0.1 μm or more, preferably to 0.5 μm or more and further preferably to 1 μm or more. The form of the α-alumina-formed member is not particularly limited, and can be properly selected according to the use.

The α-alumina-formed member obtained by the production method of the present invention can be suitably used as a cutting tool such as a tip, a drill or an end mill for which heat resistance and wear resistance are demanded, and a member such as a sliding part or metal mold used in automobiles for which low frictional resistance is demanded.

### BRIEF DESCRIPTION OF THE DRAWINGS

FIG. 1 is a TEM image of Al₂O₃ formed on a TiAlN film in which grains are largely grown in a columnar shape;

FIG. 2 is a SEM image of a surface state of an α-alumina-formed member obtained in Comparative Example;

FIG. 3 is a SEM image of the surface state of an α-alumina-formed member obtained in Example; and

FIG. 4 is a schematic view of a vacuum deposition system that is one example of an apparatus for performing a surface treatment method according to the present invention.

FIG. 5 is a SEM image of a surface state of an α-alumina-formed member obtained in another Example.

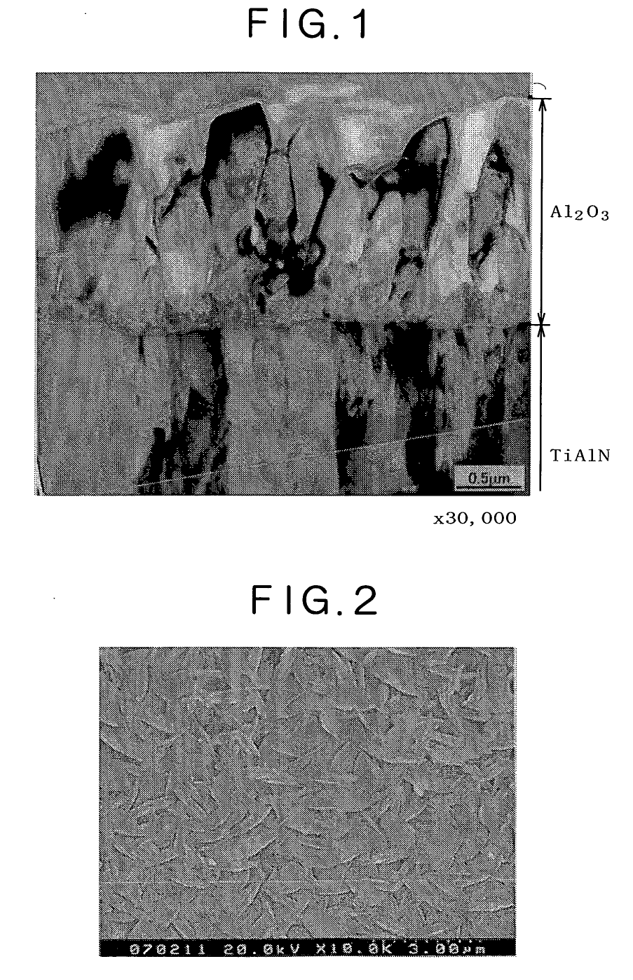

### DESCRIPTION OF THE PREFERRED EMBODIMENTS

The present invention will be more specifically described in reference to preferred embodiments. The present invention is never limited by the following preferred embodiments, and can be executed with proper modification within the scope of the invention described above and later, and such modifications can be included in the technical range of the present invention.

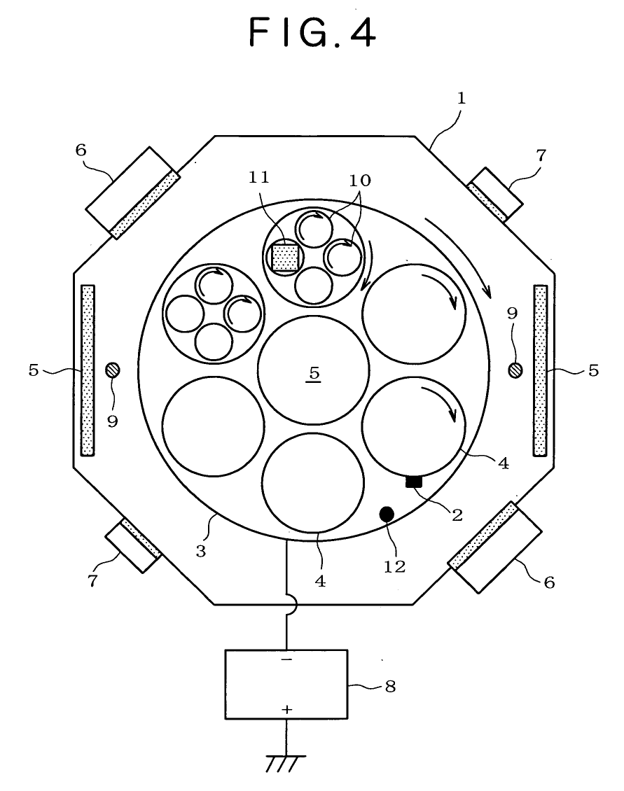

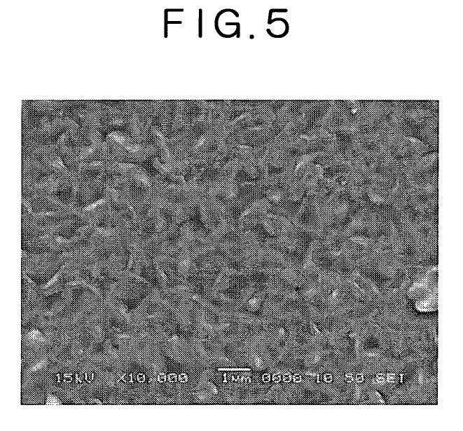

In the following embodiments, a vacuum deposition system shown in FIG. 4 was used. This vacuum deposition system, which uses a trade name “AIP-S40 hybrid coater” commercially available at Kobe Steel, Ltd., is one example of the above-mentioned “same apparatus”, which comprises physical vapor deposition (PVD) means [in this shown example, an arc ion plating (AIP) evaporation source for forming the hard film and a sputtering evaporation source for forming the α-alumina film], and ion generation means and ion collision means for performing the ion bombardment treatment. More specifically, this system comprises an arc ion plating cathode (AIP cathode) 7 as the AIP evaporation source, a sputtering cathode [magnetron sputtering cathode (UBM cathode)] 6 as the sputtering evaporation source, a thermion emitting filament 9 as the ion generation means, and a bias power source 8 as the ion collision means. In the drawing, denoted at 1 is a chamber, 2 is a base material, 3 and 4 are a base material rotating mechanism (a rotary table 3 and a planetary rotating jig 4) in pair, and 5 is heating means (heater).

The chamber 1 of this system is adapted to be capable of constituting and keeping a vacuum state, and includes the heater 5 capable of adjusting the internal temperature of the chamber 1, and the rotary table 3 capable of disposing a plurality of planetary jigs 4 thereon. By operating this system, the rotary table 3 mounted with a plurality of the planetary jigs 4 can be rotated (revolved) simultaneously with the rotation of the planetary jigs 4 themselves (the rotation around their own axes). Further, a rotary member 10 having a tool rotating jig is attached onto the planetary rotary jig 4.

In Example 1 and Comparative Example 1, a cemented carbide base material throw away tip (Reference Code: SNMN 120408) grounded to mirror face (Ra=about 0.02 μm) used for film evaluation such as film thickness, crystallinity and surface property, and a cemented carbide base material throw away tip (Reference Code: SNGA 120408) for cutting test were used as base materials of the α-alumina-formed member.

[Formation of Hard Film]

Using the system of FIG. 4, a TiAlN hard film 2-3 μm thick was formed on each of these base materials by the PVD method (arc ion plating in this example). Namely, SNMN 120408 was attached to the planetary rotary jig 4 (2 in the drawing), SNGA 120408 was attached to the rotary member 10 (11 in the drawing), nitrogen was introduced to the vacuum chamber at about 4 Pa, a voltage was applied between the cathode 7 mounted with a TiAl alloy target and the chamber 1 within the chamber 1 to generate the metal ion vapor by the arc discharge, and a bias voltage was applied by the bias power source 8 to form a hard film of Ti_{0.55}Al_{0.45}N (atomic ratio) on the base materials.

[Cleaning Treatment of Hard Film Surface]

The chamber 1 was evacuated once to vacuum, and the temperature of the base material 2 was raised to 550° C. by use of the heater 5. Ar gas was introduced into the chamber 1 at a pressure of 1.33 Pa, and discharge of 4 A was generated between the thermion emitting filament 9 and the chamber to generate Ar plasma. While keeping the generation of the Ar plasma, DC voltage pulsed at a frequency of 30 khz was applied for 18 minutes in total, or for 2 minutes at −300V, −350V, −400V, and −450V and for 10 minutes at −500V, whereby the ion bombardment treatment was performed.

[Oxidation Treatment]

The base material 2 was heated to 750° C. by the heater 5. Oxygen gas was introduced into the system at a flow rate of 300 ml/min up to a pressure of about 0.75 Pa to oxidize the surface of the base material 2.

[Formation of α-Alumina Layer]

The chamber 1 was then laid in a mixed gas atmosphere of Ar and oxygen. An average power of 5 kW was applied in total to two sputtering cathodes 6 mounted with aluminum targets to perform pulse DC sputtering, and formation of α-alumina was performed in a heating condition substantially equal to the oxidation treatment temperature to produce α-alumina-formed members. The bias voltage at that time was −300V.30 kHz pulse DC. At the time of alumina formation, the temperature of the substrate was slightly raised by the influence of heat input due to deposition. In the alumina formation, the discharge state was kept in a so-called transition mode by use of discharge voltage control and plasma emission spectrometry.

[Ion Bombardment Treatment]

In Comparative Example 1, the operation was performed no more than described above, while Ar gas was further introduced to the chamber 1 at a pressure of 2.66 Pa in Example 1, and a discharge of 10 A was generated between the thermion emitting filament 9 and the chamber 1 to generate Ar plasma. While irradiating the α-alumina-formed member 2 with the Ar plasma, DC voltage pulsed at a frequency of 30 kHz was applied for 15 minutes in total, or for 5 minutes at −300V and for 10 minutes at −400V, whereby the ion bombardment treatment was performed. In Example 2, while similarly irradiating the α-alumina-formed member 2 with the Ar plasma, DC voltage pulsed at a frequency of 30 kHz was applied for 38 minutes in total, or for 2 minutes at −200V, −250V, −300V and −350V, and for 30 minutes at −400V, whereby the ion bombardment treatment was performed and the α-alumina film surface is flattened.

The alumina films obtained in Examples 1, 2 and Comparative Example 1 were subjected to thin film X-ray diffraction analysis (thin film XRD analysis) using CuKα ray to determine the respective crystal structures from the heights of diffraction peaks of α- and γ-crystal structures at an X-ray incident angle of 1°. The surface properties were examined based on SEM images. For the machinability, a continuous cutting test was executed in the following condition by use of a SNGA 120408 cemented carbide tip with the alumina laminated film.

Work material: FCD 400

Cutting speed: 200 m/min

Feed: 0.2 mm/rpm

Depth of Cut: 3.0 mm

Condition: Dry

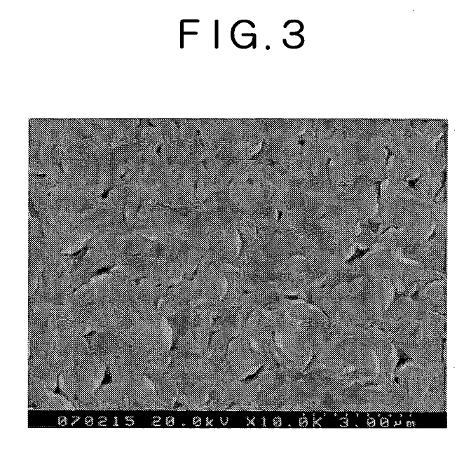

The evaluation result is shown in Table 1, and SEM images of Example 1 and Comparative Example 1 are shown in FIGS. 3 and 2, respectively. A SEM image in Example 2 is shown in FIG. 5.

TABLE 1

| | | | | | | Cutting |
|---|---|---|---|---|---|---|
| | | | | | | test |
| | | | Ion | | | (Depth of |
| | | | bombardment | | | crater |
| | TiAlN | | treatment | | | abrasion |
| | base | | after alumina | | | after 4 min. |
| | material | α-alumina | layer | Crystal | SEM | from |
| | treatment | layer | formation | structure | image | cutting) |
| Comparative | 2.1 μm | 1.7 μm | Non | Mainly α + minute γ | | 17.2 μm |
| Example 1 | | | | | | |
| Example 1 | 2.1 μm | 1.7 μm | Done | Mainly α + minute γ | | 9.65 μm |
| Example 2 | 2.4 μm | 1.7 μm | Done | Mainly α + minute γ | | — |

From the result of Table 1, both the alumina films in Comparative Example 1 and Examples 1, 2 were mainly composed of α-type crystal structure. However, in Comparative Example 1 without the ion bombardment treatment, as shown in FIG. 2, sharply-pointed mountain-shaped grains of α-alumina of several hundreds nm to several μm were clearly observed. In Example 1 with the ion bombardment treatment, as shown in FIG. 3, it was observed that sharply-pointed parts of large grains of α-alumina were rounded, With broken shapes of the grains, and the surface was relatively smoothed, compared with Comparative Example 1.

In Example 1, the depth of crater abrasion in the cutting test was small, compared with Comparative Example 1, and the tool life was enhanced. In Example 2, as is apparent from the SEM image of FIG. 5, the shape of the grains is broken to be made finer and more flattened compared to Example 1.

1. A method for producing an α-alumina layer-formed member including an alumina layer of α-type crystal structure formed on at least a partial surface of a base material, comprising:
a process for forming said alumina layer of α-type crystal structure on at least the partial surface of said base material; and
a process for performing an ion bombardment treatment to the surface of said formed alumina layer.

2. The method for producing an α-alumina layer-formed member according to claim 1, wherein said ion bombardment treatment is performed by use of an ion of rare gas in plasma.

3. The method for producing an α-alumina layer-formed member according to claim 2, wherein said rare gas is Ar.

4. The method for producing an α-alumina layer-formed member according to claim 1, wherein said ion bombardment treatment is performed by use of a metal ion generated from an electrode.

5. The method for producing an α-alumina layer-formed member according to claim 4, wherein said metal ion is an ion of Ti or Al.

6. The method for producing an α-alumina layer-formed member according to claim 1, wherein the formation of said alumina layer is performed by physical vapor deposition method.

7. The method for producing an α-alumina layer-formed member according to claim 6, wherein the process for forming said alumina layer and the process for performing said ion bombardment treatment are carried out within the same apparatus.

8. The method for producing an α-alumina layer-formed member according to claim 1, further comprising a process for forming a hard film on at least a partial surface of said base material as a pre-process of the process for forming said alumina layer so as to form the hard film as an under layer of said alumina layer.

9. The method for producing an α-alumina layer-formed member according to claim 8, wherein said hard film is composed of TiAlN.

10. The method for producing an α-alumina layer-formed member according to claim 1, wherein said alumina layer is formed so that the thickness of said alumina layer is 0.1 μm or more.

11. A surface treatment method of α-alumina layer for enhancing smoothness of a surface of an alumina layer of α-type crystal structure, comprising performing an ion bombardment treatment to the surface of said alumina layer.

12. The surface treatment method of α-alumina layer according to claim 11, wherein said ion bombardment treatment is performed by use of an ion of rare gas in plasma.

13. The surface treatment method of α-alumina layer according to claim 12, wherein said rare gas is Ar.

14. The surface treatment method of α-alumina layer according to claim 11, wherein said ion bombardment treatment is performed by use of a metal ion generated from an electrode.

15. The surface treatment method of α-alumina layer according to claim 14, wherein said metal ion is an ion of Ti or Al.
